(19) United States
(12) Patent Application Publication
(10) Pub. No.: US 2025/0311276 A1
(43) Pub. Date: Oct. 2, 2025

(54) SEMICONDUCTOR DEVICE

(71) Applicant: Fujitsu Limited, Kawasaki-shi (JP)

(72) Inventors: Atsushi YAMADA, Hiratsuka (JP); Yusuke KUMAZAKI, Atsugi (JP)

(73) Assignee: Fujitsu Limited, Kawasaki-shi (JP)

(21) Appl. No.: 19/047,697

(22) Filed: Feb. 7, 2025

(30) Foreign Application Priority Data
Mar. 27, 2024 (JP) 2024-051084

(51) Int. Cl. H10D 30/47; H01L 23/00; H02M 1/42; H03F 3/16; H03K 17/687; H10D 30/01; H10D 62/10; H10D 62/824

(52) U.S. Cl. CPC H10D 30/475; H10D 62/116; H10D 62/824; H01L 24/48; H01L 2224/48245; H01L 2924/13064; H02M 1/4233; H03F 3/165; H03K 17/687; H10D 30/015

(57) ABSTRACT

A semiconductor device includes: a channel layer; a barrier layer that is provided above the channel layer and includes indium aluminum gallium nitride (InAlGaN); a first insulating layer provided on the barrier layer; and a second insulating layer provided on the first insulating layer, wherein the first insulating layer is a silicon nitride layer that includes one or more types of group III elements included in the barrier layer.

### CROSS-REFERENCE TO RELATED APPLICATION

This application is based upon and claims the benefit of priority of the prior Japanese Patent Application No. 2024-51084, filed on Mar. 27, 2024, the entire contents of which are incorporated herein by reference.

### FIELD

The embodiments discussed herein are related to a semiconductor device.

### BACKGROUND

A large number of semiconductor devices using nitride semiconductors have been reported with respect to field effect transistors, or particularly, high electron mobility transistors (HEMTs). As the HEMT using the nitride semiconductor, an HEMT using a gallium nitride (GaN) layer as a channel layer and an aluminum gallium nitride (AlGaN) layer or an indium aluminum gallium nitride (InAlGaN) layer as a barrier layer is known. The InAlGaN layer is more likely to be lattice-matched with the GaN layer than the AlGaN layer even in a case where an aluminum (Al) composition is high, and is preferable from a viewpoint of increasing a concentration of a two-dimensional electron gas (2DEG).

Japanese Laid-open Patent Publication No. 2016-225426, Japanese Laid-open Patent Publication No. 2021-061298, U.S. Pat. Nos. 9,299,821, 9,761,438, and U.S. Patent Application Publication No. 2013/0200389 are disclosed as related art.

### SUMMARY

According to an aspect of the embodiments, a semiconductor device includes: a channel layer; a barrier layer that is provided above the channel layer and includes indium aluminum gallium nitride (InAlGaN); a first insulating layer provided on the barrier layer; and a second insulating layer provided on the first insulating layer, wherein the first insulating layer is a silicon nitride layer that includes one or more types of group III elements included in the barrier layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a cross-sectional view illustrating a semiconductor device according to a first embodiment;

FIG. 2 is a diagram illustrating an outline of distribution of ratios of elements included in a channel layer, a spacer layer, a barrier layer, a first insulating layer, and a second insulating layer;

FIG. 3 is a cross-sectional view (part 1) illustrating a method of manufacturing the semiconductor device according to the first embodiment;

FIG. 4 is a cross-sectional view (part 2) illustrating the method of manufacturing the semiconductor device according to the first embodiment;

FIG. 5 is a cross-sectional view (part 3) illustrating the method of manufacturing the semiconductor device according to the first embodiment;

FIG. 6 is a cross-sectional view (part 4) illustrating the method of manufacturing the semiconductor device according to the first embodiment;

FIG. 7 is a cross-sectional view (part 5) illustrating the method of manufacturing the semiconductor device according to the first embodiment;

FIG. 8 is a diagram illustrating current collapse of the semiconductor device according to the first embodiment;

FIG. 9 is a diagram illustrating current collapse of a semiconductor device according to a reference example;

FIG. 10 is a cross-sectional view illustrating another example of a method of forming the first insulating layer and the second insulating layer;

FIG. 11 is a diagram illustrating a discrete package according to a second embodiment;

FIG. 12 is a connection diagram illustrating a power factor correction (PFC) circuit according to a third embodiment;

FIG. 13 is a connection diagram illustrating a power supply device according to a fourth embodiment; and

FIG. 14 is a connection diagram illustrating an amplifier according to a fifth embodiment.

### DESCRIPTION OF EMBODIMENTS

However, although an insulating layer such as a silicon nitride (SIN) layer is formed over the barrier layer by a plasma chemical vapor deposition (CVD) method, a surface of the InAlGaN layer is more likely to be damaged by plasma than that of the AlGaN layer. When there is a defect associated with the damage in the surface of the barrier layer, current collapse is likely to occur, and it is difficult to improve an output.

An object of the present disclosure is to provide a semiconductor device capable of improving an output.

Hereinafter, embodiments of the present disclosure will be specifically described with reference to the accompanying drawings. Note that, in the present description and the drawings, components having substantially the same functional configuration will be denoted by the same reference sign, and redundant description may be omitted.

### First Embodiment

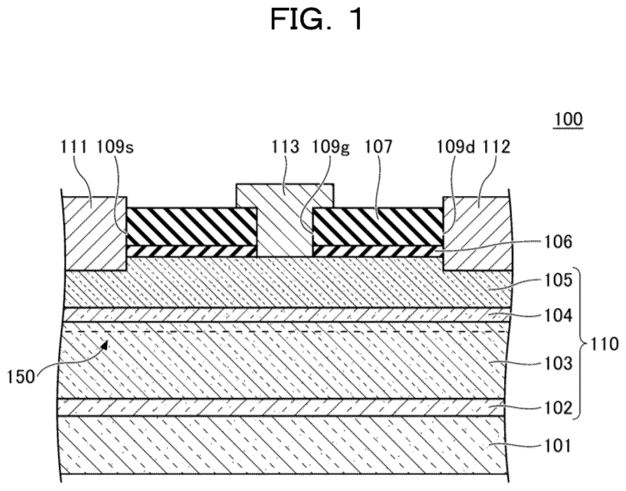

A first embodiment will be described. The first embodiment relates to a semiconductor device including a high electron mobility transistor (HEMT). FIG. 1 is a cross-sectional view illustrating the semiconductor device according to the first embodiment.

As illustrated in FIG. 1, a semiconductor device 100 according to the first embodiment includes a substrate 101 and a nitride semiconductor laminated structure 110 provided above the substrate 101. The nitride semiconductor laminated structure 110 includes a nucleation layer 102, a channel layer 103, a spacer layer 104, and a barrier layer 105. The nucleation layer 102 is provided on the substrate 101. The channel layer 103 is provided on the nucleation layer 102. The spacer layer 104 is provided on the channel layer 103. The barrier layer 105 is provided on the spacer layer 104.

The substrate 101 is, for example, a semi-insulating silicon carbide (SiC) substrate. The nucleation layer 102 is, for example, an aluminum nitride (AlN) layer having a thickness of 5 nm or more and 150 nm or less. The channel layer 103 is, for example, a gallium nitride (GaN) layer having a thickness of 1 μm or more and 5 μm or less. The spacer layer 104 is, for example, an Al₂Ga₁₋₂N layer (0.40≤z≤1.00) having a thickness of 0.5 nm or more and 3 nm or less. For example, the spacer layer 104 is, for example, an aluminum gallium nitride (AlGaN) layer having an aluminum (Al) composition z of 0.40 or more and 1.00 or less. The barrier layer 105 includes an indium aluminum gallium nitride (InAlGaN). The barrier layer 105 is, for example, an Inₓ₁Alₓ₂Ga₁₋ₓ₁₋ₓ₂N layer (0.00<x1≤0.20, 0.10≤x2<1.00) having a thickness of 4 nm or more and 10 nm or less. For example, the barrier layer 105 is, for example, an InAlGaN layer having an indium (In) composition x1 of more than 0.00 and 0.20 or less and an Al composition x2 of 0.10 or more and less than 1.00. There is a two-dimensional electron gas (2DEG) 150 near an upper surface of the channel layer 103.

The semiconductor device 100 includes a first insulating layer 106 and a second insulating layer 107. The first insulating layer 106 is provided on the barrier layer 105, and the second insulating layer 107 is provided on the first insulating layer 106. The first insulating layer 106 is, for example, a silicon nitride (SiN) layer having a thickness of 1 nm or more and 5 nm or less and including one or more types of group III elements included in the barrier layer 105. The second insulating layer 107 includes, for example, a layer of a nitride, oxide, or oxynitride of silicon (Si), Al, hafnium (Hf), zirconium (Zr), titanium (Ti), tantalum (Ta), or tungsten (W), and is preferably a Si nitride (SiN) layer. A thickness of the second insulating layer 107 is, for example, 2 nm or more and 500 nm or less, and preferably about 100 nm.

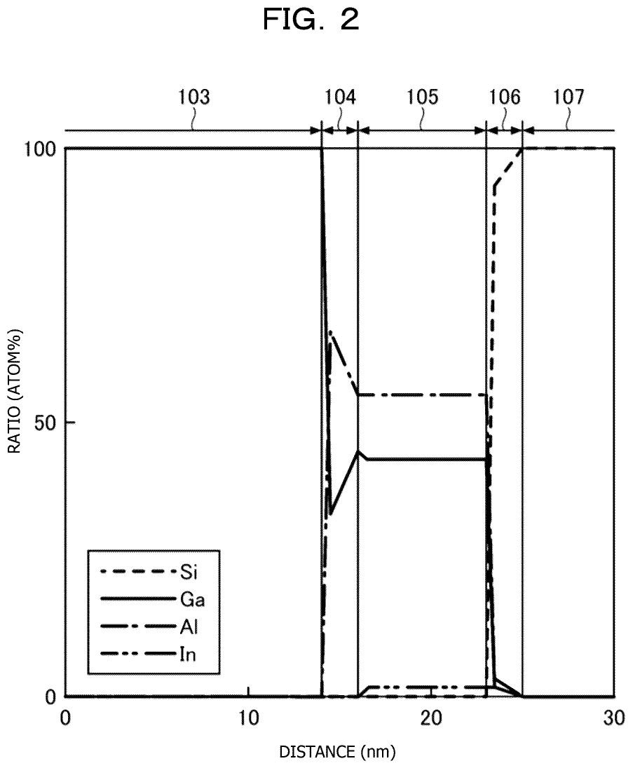

FIG. 2 is a diagram illustrating an outline of distribution of ratios of elements included in the channel layer 103, the spacer layer 104, the barrier layer 105, the first insulating layer 106, and the second insulating layer 107. In FIG. 2, the ratios of the elements other than nitrogen (N) in the respective layers are schematically illustrated. In FIG. 2, a horizontal axis represents a distance based on one point in the channel layer 103, and a vertical axis represents the ratio of the elements. An actual ratio of the elements in each layer may be acquired by, for example, transmission electron microscope (TEM)-energy dispersive X-ray spectroscopy (EDX).

An element separation region defining an element region is formed in the nitride semiconductor laminated structure 110, and a recess 109s for a source and a recess 109d for a drain are formed in a laminated body of the barrier layer 105, the first insulating layer 106, and the second insulating layer 107 in the element region. The recesses 109s and 109d penetrate the first insulating layer 106 and the second insulating layer 107. A bottom surface of the recess 109s and a bottom surface of the recess 109d are in the barrier layer 105.

An opening 109g for a gate is formed in a laminated body of the first insulating layer 106 and the second insulating layer 107. The opening 109g penetrates the first insulating layer 106 and the second insulating layer 107. The opening 109g is positioned between a source electrode 111 and a drain electrode 112 in planar view.

The semiconductor device 100 includes the source electrode 111, the drain electrode 112, and a gate electrode 113. The source electrode 111 is provided in the recess 109s, and the drain electrode 112 is provided in the recess 109d. The gate electrode 113 is provided on the second insulating layer 107, and is in contact with the barrier layer 105 through the opening 109g.

Each of the source electrode 111 and the drain electrode 112 includes, for example, a Ta film having a thickness of 10 nm or more and 50 nm or less and an Al film having a thickness of 100 nm or more and 500 nm or less over the Ta film, and are in ohmic contact with the nitride semiconductor laminated structure 110. The gate electrode 113 includes, for example, a nickel (Ni) film having a thickness of 10 nm or more and 50 nm or less and a gold (Au) film having a thickness of 300 nm or more and 500 nm or less over the Ni film.

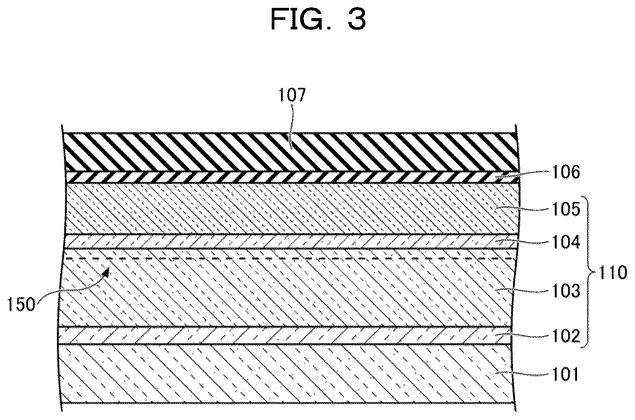

Next, a method of manufacturing the semiconductor device 100 according to the first embodiment will be described. FIGS. 3 to 7 are cross-sectional views illustrating the method of manufacturing the semiconductor device 100 according to the first embodiment.

First, as illustrated in FIG. 3, the nitride semiconductor laminated structure 110 is formed on the substrate 101. In the formation of the nitride semiconductor laminated structure 110, the nucleation layer 102, the channel layer 103, the spacer layer 104, and the barrier layer 105 are formed by, for example, a metal organic vapor phase epitaxy (MOVPE) method. In the formation of the nitride semiconductor laminated structure 110, when the GaN layer is grown, a mixed gas of a trimethylgallium (TMGa) gas that is a gallium (Ga) source and an ammonia (NH₃) gas that is an N source is used as a source gas. When the AlN layer is grown, a mixed gas of a trimethylaluminum (TMAl) gas that is an Al source and the NH₃ gas is used as the source gas. When the AlGaN layer is grown, a mixed gas of the TMAl gas, the TMGa gas, and the NH₃ gas is used as the source gas. When the InAlGaN layer is grown, a mixed gas of the TMAl gas, the TMGa gas, a trimethylindium (TMIn) gas, and the NH₃ gas is used as the source gas. Presence or absence of supply and flow rates of the TMAl gas, the TMGa gas, and the TMIn gas are appropriately set according to a composition of a nitride semiconductor layer to be grown. A hydrogen (H₂) gas or a nitrogen (N₂) gas is used as a carrier gas. For example, it is assumed that a growth pressure is about 1 kPa to 100 kPa, and a growth temperature is about 700° C. to 1200° C.

Next, the first insulating layer 106 is formed on the barrier layer 105. The first insulating layer 106 is formed in situ following the formation of the nitride semiconductor laminated structure 110. When the first insulating layer 106 is formed, a mixed gas of a silane (SiH₄) gas that is a Si source, the TMIn gas, the TMAl gas, the TMGa gas, and the NH₃ gas is used as the source gas. Presence or absence of supply and flow rates of the TMIn gas, the TMAl gas, and the TMGa gas are appropriately set according to a composition of the first insulating layer 106. The H₂ gas or the N₂ gas is used as the carrier gas.

Thereafter, the second insulating layer 107 is formed on the first insulating layer 106. The second insulating layer 107 is formed by, for example, a plasma chemical vapor deposition (CVD) method. The second insulating layer 107 may be formed by an atomic layer deposition (ALD) method or a sputtering method. In a case where the second insulating layer 107 is formed by the plasma CVD method, for example, a condition that a film density of the second insulating layer 107 is 2.64 g/cm³ or more is adopted.

Subsequently, the element separation region that defines the element region is formed in the nitride semiconductor laminated structure 110. In the formation of the element separation region, for example, a photoresist pattern for exposing a region where the element separation region is to be formed is formed over the nitride semiconductor laminated structure 110, and argon (Ar) ions or the like are implanted using this pattern as a mask. Dry etching using a chlorine-based gas may be performed using this pattern as an etching mask.

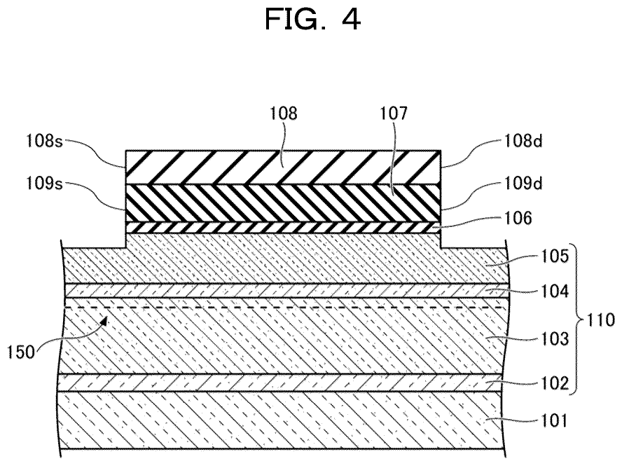

Next, as illustrated in FIG. 4, a surface protective film 108 is formed on the second insulating layer 107. The surface protective film 108 includes, for example, a layer of an oxide, nitride, or oxynitride of Si, Al, Hf, Zr, Ti, Ta, or W, and is preferably a Si oxide (SiO₂) layer. The surface protective film 108 may be formed by, for example, the plasma CVD method. The surface protective film 108 may be formed by the ALD method or the sputtering method.

Thereafter, openings 108s and 108d are formed in the surface protective film 108, and the recesses 109s and 109d are formed in the laminated body of the barrier layer 105, the first insulating layer 106, and the second insulating layer 107. In the formation of the openings 108s and 108d and the recesses 109s and 109d, for example, a photoresist pattern for exposing regions where the recesses 109s and 109d are to be formed is formed over the surface protective film 108 by photolithography. Then, dry etching using a fluorine-based gas or a chlorine-based gas is performed using this pattern as an etching mask. The recesses 109s and 109d are formed such that the bottom surfaces thereof are positioned in the barrier layer 105.

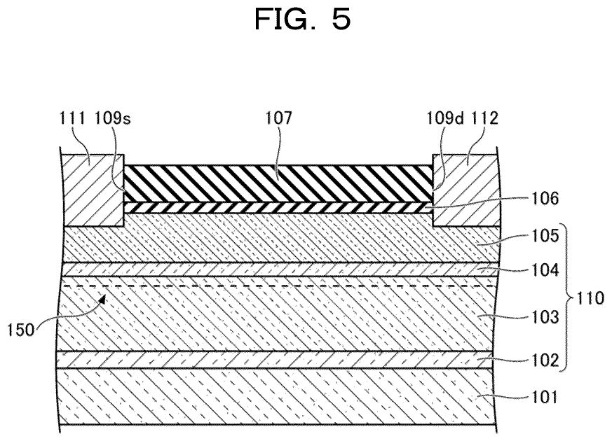

Subsequently, as illustrated in FIG. 5, the source electrode 111 is formed in the recess 109s, and the drain electrode 112 is formed in the recess 109d. The source electrode 111 and the drain electrode 112 may be formed by, for example, a lift-off method. For example, a photoresist pattern for exposing regions where the source electrode 111 and the drain electrode 112 are to be formed is formed, a metal film is formed by a vapor deposition method using this pattern as a growth mask, and this pattern is removed together with the metal film thereon. In the formation of the metal film, for example, a Ta film is formed, and an Al film is formed thereon. Next, for example, heat treatment is performed at 400° C. to 1000° C. (for example, 550° C.) in a nitrogen atmosphere to establish ohmic characteristics. After the source electrode 111 and the drain electrode 112 are formed, the surface protective film 108 is removed.

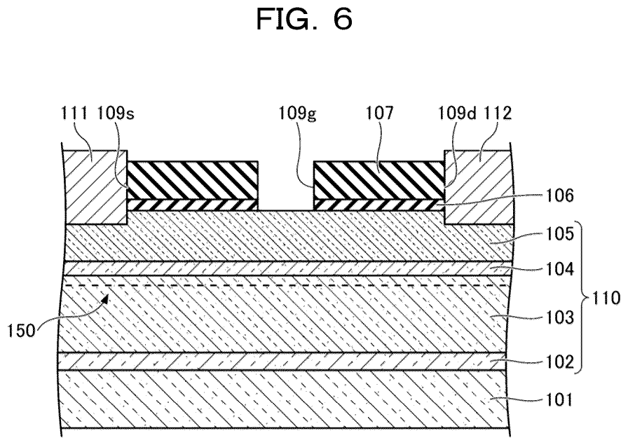

Thereafter, as illustrated in FIG. 6, the opening 109g is formed in the laminated body of the first insulating layer 106 and the second insulating layer 107. In the formation of the opening 109g, for example, a photoresist pattern for exposing a region where the opening 109g is to be formed is formed over the second insulating layer 107 by the photolithography, and dry etching using a fluorine-based gas is performed using this pattern as an etching mask. Wet etching using hydrofluoric acid, buffered hydrofluoric acid, or the like may be performed instead of the dry etching.

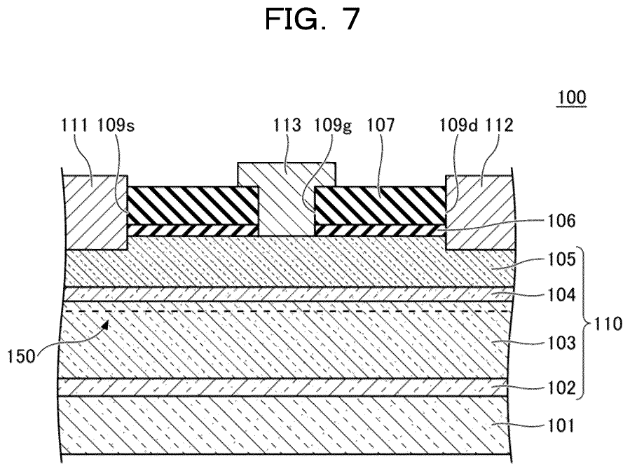

Subsequently, as illustrated in FIG. 7, the gate electrode 113 in contact with the barrier layer 105 through the opening 109g is formed on the second insulating layer 107. The gate electrode 113 may be formed by, for example, the lift-off method. For example, a photoresist pattern for exposing a region where the gate electrode 113 is to be formed is formed, a metal film is formed by the vapor deposition method using this pattern as a growth mask, and this pattern is removed together with the metal film thereon. In the formation of the metal film, for example, a Ni film is formed, and a Au film is formed thereon.

In this manner, the semiconductor device 100 according to the first embodiment may be manufactured.

In the semiconductor device 100, the first insulating layer 106 is provided on the barrier layer 105, and the second insulating layer 107 is provided on the first insulating layer 106. Furthermore, the first insulating layer 106 may be formed by the MOVPE method in situ following the nitride semiconductor laminated structure 110. Therefore, the barrier layer 105 is less likely to be damaged when the first insulating layer 106 is formed. Furthermore, even when the second insulating layer 107 is formed under the condition that the film density is 2.64 g/cm³ or more, the barrier layer 105 is less likely to be damaged because the first insulating layer 106 is formed. Therefore, according to the semiconductor device 100, since the number of defects in a surface of the barrier layer 105 is small and current collapse is reduced, an output may be improved. Furthermore, it is also possible to suppress on-resistance to be low.

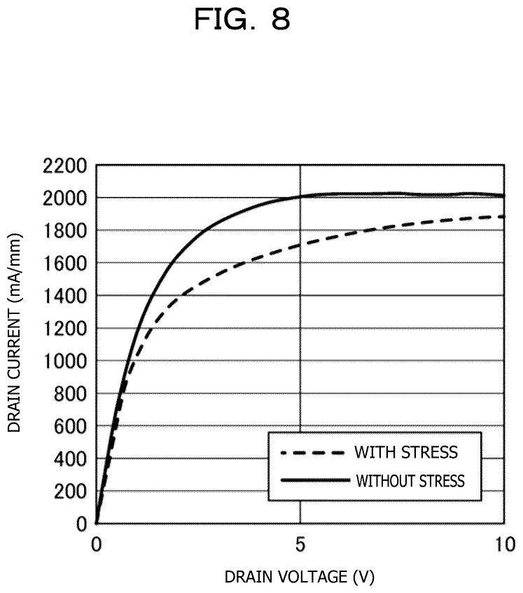

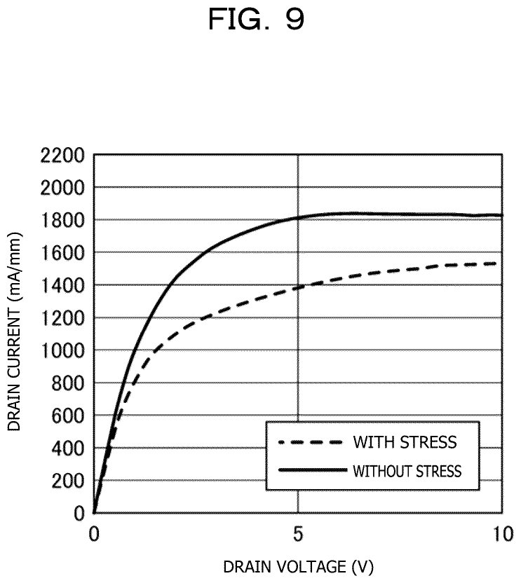

Here, the current collapse of the first embodiment and a reference example will be described. FIG. 8 is a diagram illustrating the current collapse of the semiconductor device according to the first embodiment. FIG. 9 is a diagram illustrating the current collapse of a semiconductor device according to the reference example. In the semiconductor device according to the reference example, the second insulating layer 107 is directly formed on the barrier layer 105 by the plasma CVD method without forming the first insulating layer 106. Other configurations of the reference example are similar to those of the first embodiment. As illustrated in FIGS. 8 and 9, in the first embodiment, the current collapse is reduced as compared with the reference example. Therefore, according to the first embodiment, a higher output than that of the reference example may be obtained. This is because, in the reference example, the barrier layer 105 is damaged when the second insulating layer 107 is formed, and there are many defects in the surface of the barrier layer 105.

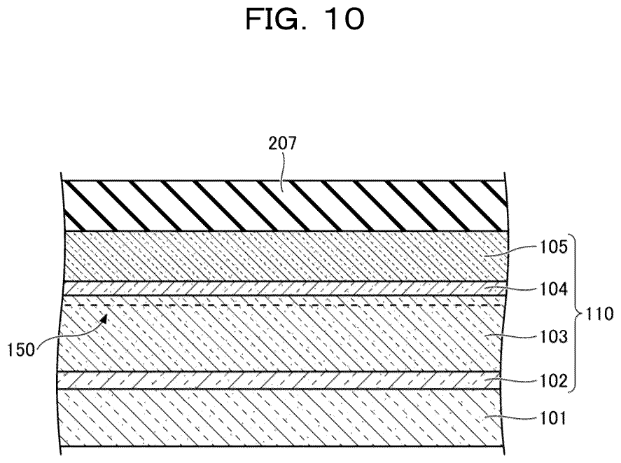

Note that the first insulating layer 106 and the second insulating layer 107 may be formed as follows. FIG. 10 is a cross-sectional view illustrating another example of a method of forming the first insulating layer and the second insulating layer.

In this method, as illustrated in FIG. 10, a SiN layer is formed as an insulating layer 207 on the barrier layer 105 by the plasma CVD method. A thickness of the insulating layer 207 is equal to a thickness of the laminated body of the first insulating layer 106 and the second insulating layer 107 to be formed. The insulating layer 207 is formed under a condition that a film density is 2.50 g/cm³ or more and 2.56 g/cm³ or less. For example, the insulating layer 207 is formed under the lower power condition than the condition under which the second insulating layer 107 is formed by the manufacturing method described above. When the insulating layer 207 is formed under such a condition, damage is less likely to occur in the surface of the barrier layer 105. After the formation of the insulating layer 207, heat treatment is performed at a temperature of about 600° C. or more and 800° C. or less. During this heat treatment, a part of the group III elements included in the barrier layer 105 diffuses into the insulating layer 207, and the film density of the insulating layer 207 increases. As a result, the laminated body of the first insulating layer 106 and the second insulating layer 107 is obtained from the insulating layer 207. The film density of the second insulating layer 107 formed by this method is, for example, 2.64 g/cm³ or more and 2.70 g/cm³ or less.

The thickness of the first insulating layer 106 is not limited, but is preferably 1 nm or more and 5 nm or less. When the thickness of the first insulating layer 106 is less than 1 nm, an effect of suppressing damage may be reduced. When the thickness of the first insulating layer 106 exceeds 5 nm, a cost for the effect may increase. The thickness of the first insulating layer 106 is more preferably 1 nm or more and 3 nm or less.

In the first insulating layer 106, a ratio of the group III elements to a total amount of silicon and the group III elements is not limited, but is preferably 1 atom % or more and 5 atom % or less. When this ratio is less than 1 atom %, the effect of suppressing damage may be reduced. When this ratio is more than 5 atom %, an insulation property of the first insulating layer 106 may be deteriorated. This ratio is preferably 1 atom % or more and 3 atom % or less.

A composition of the spacer layer 104 is represented by Al₂Ga₁₋₂N (0.40≤z≤1.00), but the Al composition z may be 1.00, and the spacer layer 104 may be an AlN layer. The spacer layer 104 may not be provided, and the channel layer 103 and the barrier layer 105 may be in direct contact with each other.

### Second Embodiment

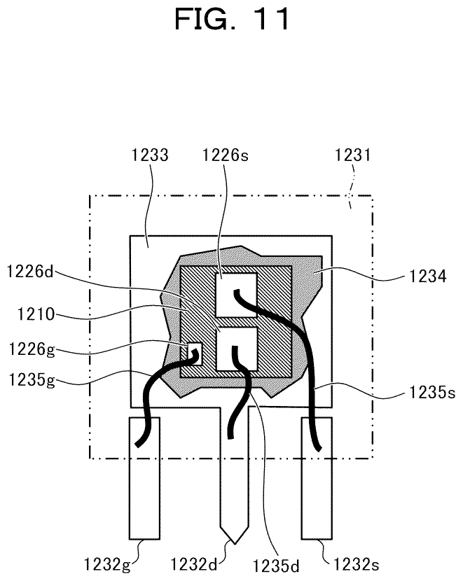

Next, a second embodiment will be described. The second embodiment relates to a discrete package of an HEMT. FIG. 11 is a diagram illustrating the discrete package according to the second embodiment.

In the second embodiment, as illustrated in FIG. 11, a back surface of a semiconductor device 1210 having a structure similar to that of the first embodiment is secured to a land (die pad) 1233 with a die attach agent 1234 such as solder. Furthermore, a wire 1235d such as an Al wire is coupled to a drain pad 1226d to which a drain electrode 112 is coupled, and the other end of the wire 1235d is coupled to a drain lead 1232d integrated with the land 1233. A wire 1235s such as an Al wire is coupled to a source pad 1226s coupled to a source electrode 111, and the other end of the wire 1235s is coupled to a source lead 1232s independent of the land 1233. A wire 1235g such as an Al wire is coupled to a gate pad 1226g coupled to a gate electrode 113, and the other end of the wire 1235g is coupled to a gate lead 1232g independent of the land 1233. Additionally, the land 1233, the semiconductor device 1210, and the like are packaged with a mold resin 1231 so that a part of the gate lead 1232g, a part of the drain lead 1232d, and a part of the source lead 1232s stick out.

Such a discrete package may be manufactured as follows, for example. First, the semiconductor device 1210 is secured to the land 1233 of a lead frame using the die attach agent 1234 such as solder. Next, bonding is performed using the wires 1235g, 1235d, and 1235s, so that the gate pad 1226g is coupled to the gate lead 1232g of the lead frame, the drain pad 1226d is coupled to the drain lead 1232d of the lead frame, and the source pad 1226s is coupled to the source lead 1232s of the lead frame. Thereafter, sealing using the mold resin 1231 is performed by a transfer molding method. Subsequently, the lead frame is cut off and detached.

### Third Embodiment

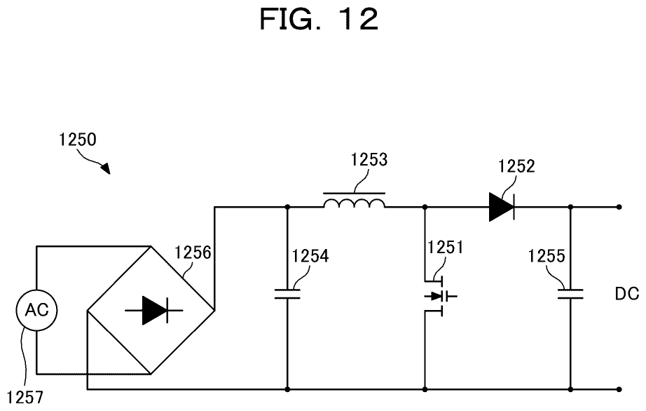

Next, a third embodiment will be described. The third embodiment relates to a power factor correction (PFC) circuit including an HEMT. FIG. 12 is a connection diagram illustrating the PFC circuit according to the third embodiment.

A PFC circuit 1250 is provided with a switch element (transistor) 1251, a diode 1252, a choke coil 1253, capacitors 1254 and 1255, a diode bridge 1256, and an alternating-current power supply (AC) 1257. Additionally, a drain electrode of the switch element 1251 is coupled to an anode terminal of the diode 1252 and one terminal of the choke coil 1253. A source electrode of the switch element 1251 is coupled to one terminal of the capacitor 1254 and one terminal of the capacitor 1255. The other terminal of the capacitor 1254 and the other terminal of the choke coil 1253 are coupled. The other terminal of the capacitor 1255 and a cathode terminal of the diode 1252 are coupled. Furthermore, a gate driver is coupled to a gate electrode of the switch element 1251. The AC 1257 is coupled between both of the terminals of the capacitor 1254 via the diode bridge 1256. A direct-current power supply (DC) is coupled between both of the terminals of the capacitor 1255. Additionally, in the present embodiment, a semiconductor device having a structure similar to that of the first embodiment is used for the switch element 1251.

In the manufacturing of the PFC circuit 1250, for example, the switch element 1251 is coupled to the diode 1252, the choke coil 1253, and the like using solder or the like.

### Fourth Embodiment

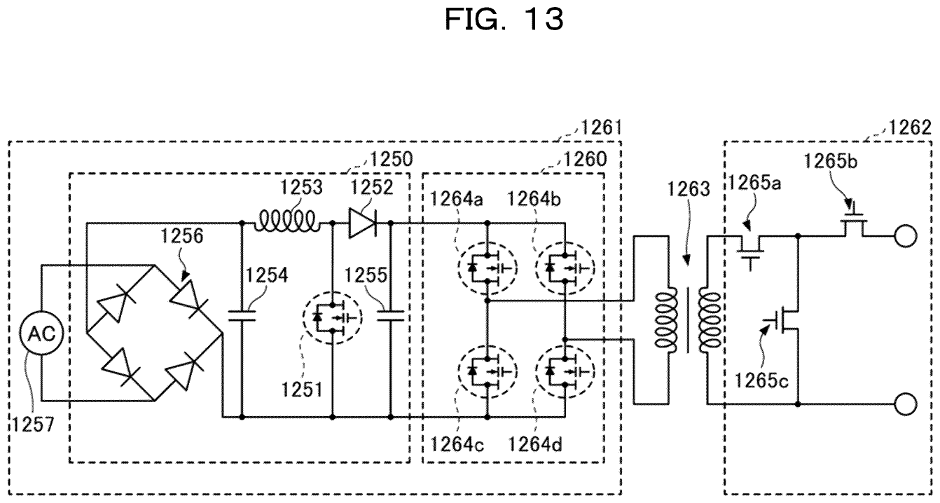

Next, a fourth embodiment will be described. The fourth embodiment relates to a power supply device including an HEMT, suitable for a server power supply. FIG. 13 is a connection diagram illustrating the power supply device according to the fourth embodiment.

The power supply device is provided with a high-voltage primary-side circuit 1261, a low-voltage secondary-side circuit 1262, and a transformer 1263 disposed between the primary-side circuit 1261 and the secondary-side circuit 1262.

The primary-side circuit 1261 is provided with the PFC circuit 1250 according to the third embodiment, and an inverter circuit, for example, a full-bridge inverter circuit 1260 coupled between both of the terminals of the capacitor 1255 of the PFC circuit 1250. The full-bridge inverter circuit 1260 is provided with a plurality of (here, four) switch elements 1264a, 1264b, 1264c, and 1264d.

The secondary-side circuit 1262 is provided with a plurality of (here, three) switch elements 1265a, 1265b, and 1265c.

In the present embodiment, semiconductor devices each having a structure similar to that of the first embodiment are used for the switch element 1251 of the PFC circuit 1250 constituting the primary-side circuit 1261, and the switch elements 1264a, 1264b, 1264c, and 1264d of the full-bridge inverter circuit 1260. On the other hand, normal metal-insulator-semiconductor (MIS) field effect transistors (FETs) using silicon are used for the switch elements 1265a, 1265b, and 1265c of the secondary-side circuit 1262.

### Fourth Embodiment

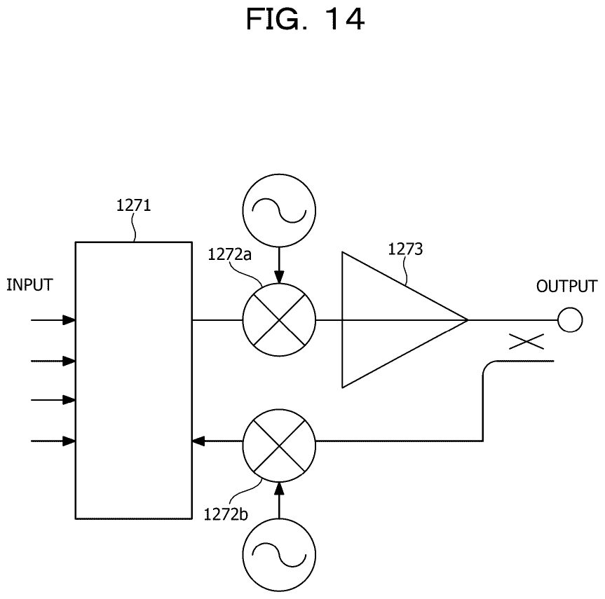

Next, a fourth embodiment will be described. The fifth embodiment relates to an amplifier including an HEMT. FIG. 14 is a connection diagram illustrating the amplifier according to the fifth embodiment.

The amplifier is provided with a digital predistortion circuit 1271, mixers 1272a and 1272b, and a power amplifier 1273.

The digital predistortion circuit 1271 compensates for nonlinear distortion of an input signal. The mixer 1272a mixes the input signal compensated for its nonlinear distortion with an alternating current signal. The power amplifier 1273 includes a semiconductor device having a structure similar to that of the first embodiment, and amplifies the input signal mixed with the alternating current signal. Note that, in the present embodiment, switching is performed with a switch, for example, so that the signal on an output side may be mixed with an alternating current signal by the mixer 1272b and be transmitted to the digital predistortion circuit 1271. This amplifier may be used as a high-frequency amplifier or a high-power amplifier. The high-frequency amplifier may be used in, for example, a transmission/reception device for mobile phone base stations, a radar device, and a microwave generator.

As a substrate, a silicon carbide (SiC) substrate, a sapphire substrate, a silicon substrate, an AlN substrate, a GaN substrate, or a diamond substrate may be used. The substrate may be conductive, semi-insulating, or insulating.

The structures of the gate electrode, the source electrode, and the drain electrode are not limited to those of the embodiments described above. For example, these may be configured by a single layer. Furthermore, the method of forming these is not limited to the lift-off method. Moreover, as long as the ohmic characteristics are obtained, the heat treatment after the formation of the source electrode and the drain electrode may be omitted. The heat treatment may be performed after the formation of the gate electrode.

Furthermore, an n-type GaN region may be formed at a portion immediately below the source electrode and the drain electrode of the nitride semiconductor laminated structure. This n-type GaN region may be formed by, for example, ion implantation or regrowth.

Although the preferred embodiments and the like have been described in detail above, various modifications and substitutions may be made to the embodiments described above and the like, without being limited to the embodiments described above and the like, and without departing from the scope of the claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a channel layer;
a barrier layer that is provided above the channel layer and includes indium aluminum gallium nitride (InAlGaN);
a first insulating layer provided on the barrier layer; and
a second insulating layer provided on the first insulating layer,
wherein the first insulating layer is a silicon nitride layer that includes one or more types of group III elements included in the barrier layer.

2. The semiconductor device according to claim 1, wherein the first insulating layer has a thickness of 1 nm or more and 5 nm or less.

3. The semiconductor device according to claim 1, wherein, in the first insulating layer, a ratio of the group III elements to a total amount of silicon and the group III elements is 1 atom % or more and 5 atom % or less.

4. The semiconductor device according to claim 1, wherein the second insulating layer includes silicon nitride.

5. The semiconductor device according to claim 1, further comprising a spacer layer between the channel layer and the barrier layer.

6. The semiconductor device according to claim 5, wherein the spacer layer includes aluminum nitride (AlN) or aluminum gallium nitride (AlGaN).

7. A method of manufacturing a semiconductor device, the method comprising:
forming a barrier layer that includes indium aluminum gallium nitride (InAlGaN) above a channel layer;
forming a first insulating layer on the barrier layer; and
forming a second insulating layer on the first insulating layer by a plasma chemical vapor deposition method,
wherein the first insulating layer is a silicon nitride layer that includes one or more types of group III elements included in the barrier layer.

8. The method according to claim 7, wherein the first insulating layer is formed in situ with the barrier layer.

9. An amplifier comprising the semiconductor device according to claim 1.

10. A power supply device comprising the semiconductor device according to claim 1.
